(19) United States
(12) Patent Application Publication
(10) Pub. No.: US 2026/0177715 A1
(43) Pub. Date: Jun. 25, 2026

(54) METHODS OF REPRESENTATIVE ELEMENTARY VOLUME (REV) CROSS-SCALE SIMULATION FOR ADAPTIVE CONTROL IN TUNNEL OPERATIONS

(71) Applicant: SHANDONG UNIVERSITY, Jinan (CN)

(72) Inventors: Shucai LI, Jinan (CN); Zongqing ZHOU, Jinan (CN); Liping LI, Jinan (CN); Chunjin LIN, Jinan (CN); Shaoshuai SHI, Jinan (CN); Chenglu GAO, Jinan (CN); Cheche WEI, Jinan (CN); Chengshun SHANG, Jinan (CN); Songsong BAI, Jinan (CN)

(73) Assignee: SHANDONG UNIVERSITY, Jinan (CN)

(21) Appl. No.: 19/540,702

(22) Filed: Feb. 15, 2026

Related U.S. Application Data
(63) Continuation-in-part of application No. 17/630,231.

(30) Foreign Application Priority Data
Apr. 30, 2020 (CN) 202010363419.9

(51) Int. Cl. G01V 1/28; E21B 44/00; G06F 30/15

(52) U.S. Cl. CPC G01V 1/282; E21B 44/00; G06F 30/15

(57) ABSTRACT

Disclosed is a method and system of REV cross-scale simulation for adaptive control in tunnel operations. The method includes establishing a rock mass engineering scale calculation model; dividing the rock mass engineering scale calculation model into a plurality of finite elements, and performing mesh division on the finite elements; presetting a plurality of test blasting parameters; determining a dynamic load based on at least one of the test blasting parameters; applying a boundary condition to the rock mass engineering scale calculation model; determining force information and first motion information of element nodes of the finite elements and determining a failure state of each finite element using a continuous medium method; determining second motion information of particles of an REV model inside at least one failed finite element using a discontinuous medium method; determining an optimal blasting parameter; and controlling a blasting robot to perform a blasting operation.

### CROSS-REFERENCE TO RELATED APPLICATIONS

This application is a continuation-in-part of U.S. application Ser. No. 17/630,231, filed on Jan. 26, 2022, which is a U.S. national phase application under 35 U.S.C. § 371 of International Patent Application No. PCT/CN2020/122785, filed on Oct. 22, 2020, and which claims priority to Chinese Patent Application No. 202010363419.9, filed on Apr. 30, 2020, the entire contents of each of which are incorporated herein by reference.

### TECHNICAL FIELD

The present disclosure relates to the field of rock mass simulation calculation technology, and in particular, to a method and system of representative elementary volume (REV) cross-scale simulation for adaptive control in tunnel operations.

### BACKGROUND

As a scale of underground engineering and tunnel engineering construction continues to expand, site conditions become increasingly complex, leading to engineering problems that are more difficult to solve. These geotechnical engineering problems often exhibit high anisotropy, heterogeneity, and discontinuity. Traditional analytical methods are almost incapable of performing mechanical analysis on these problems. Physical test methods cannot be widely applied on a large scale due to defects such as high costs and long cycles. In contrast, numerical simulation methods are widely used due to low cost and operational convenience.

With computer technology advancing towards petaflop or even higher levels, numerical simulation theories and methods for solving the geotechnical engineering problems develop rapidly. Successful application of various numerical methods deepens people's understanding of geotechnical engineering phenomena and strongly promotes a development of geotechnical engineering.

Existing numerical simulation methods are mainly divided into two categories: continuous medium methods and discontinuous medium methods. In the study and simulation of the geotechnical engineering problems, complex features of the geotechnical engineering problems make it difficult for simulation methods based on continuous medium mechanics theory (such as a finite element method, a boundary element method, a finite difference method, or the like) to fundamentally reveal laws of force transmission and microscopic mechanisms of deformation development. A discrete element method is a numerical simulation method based on discontinuous medium mechanics first proposed by Cundall in 1971. The discrete element method treats a rock mass as discrete rigid or deformable blocks cut by structural planes such as faults, joints, and fractures. The discrete element method solves displacements of the blocks by establishing Newton's equations of motion and adopting a difference scheme. Therefore, the discrete element method may effectively simulate a deformation process of discrete particle assemblies such as rock masses, avoiding a derivation of complex constitutive relationships. This feature makes the discrete element method widely applicable in fields such as rock mechanics, soil mechanics, and fluid mechanics.

However, when the discrete element method is used for engineering-scale simulation calculations, a count of calculation particles reaches millions, tens of millions, or even more. The required computational resources and time increase exponentially, posing a huge challenge to computing and analysis capabilities.

Therefore, it is necessary to provide a method and system of REV cross-scale simulation for adaptive control in tunnel operations to improve a calculation efficiency while ensuring a simulation accuracy.

### SUMMARY

One or more embodiments of the present disclosure provide a method of representative elementary volume (REV) cross-scale simulation for adaptive control in tunnel operations. The method includes: establishing a rock mass engineering scale calculation model, and assigning particle parameters to the rock mass engineering scale calculation model; dividing the rock mass engineering scale calculation model into a plurality of finite elements, and performing mesh division on the plurality of finite elements, wherein a volume of each of the plurality of finite elements is equal to a representative elementary volume (REV); presetting a plurality of test blasting parameters, wherein each test blasting parameter includes an explosive type, a charge amount, a blasting hole position, and a detonation sequence; determining a dynamic load based on at least one of the plurality of test blasting parameters, wherein the dynamic load includes a pressure-time curve; applying a boundary condition to the rock mass engineering scale calculation model, wherein the boundary condition includes the dynamic load; determining force information and first motion information of element nodes of the plurality of finite elements, and determining a failure state of each of the plurality of finite elements using a continuous medium method; determining second motion information of particles of an REV model inside at least one failed finite element using a discontinuous medium method; determining a propagation path of a blast stress wave in a rock mass based on the first motion information of the element nodes of the plurality of finite elements; determining a surrounding rock damage degree corresponding to each test blasting parameter based on the propagation path and the failure state of each of the plurality of finite elements; determining a fragmentation efficiency corresponding to each test blasting parameter based on the second motion information of the particles of the REV model inside the at least one failed finite element; determining an optimal blasting parameter from the plurality of test blasting parameters based on the surrounding rock damage degree and the fragmentation efficiency; controlling a blasting robot to perform a blasting operation based on the optimal blasting parameter, including: controlling the blasting robot to load an explosive into an optimal blasting hole position based on an optimal explosive type and an optimal charge amount; and detonating the explosive based on an optimal detonation sequence to complete a blasting task for the rock mass.

One or more embodiments of the present disclosure provide a system of representative elementary volume (REV) cross-scale simulation for adaptive control in tunnel operations. The system includes: at least one memory for storing computer instructions; and at least one processor configured to communicate with the at least one memory. When the at least one processor executes the computer instructions, the at least one processor is configured to perform the method of representative elementary volume (REV) cross-scale simulation for adaptive control in tunnel operations according to any one of the embodiments of the present disclosure.

One or more embodiments of the present disclosure provide a non-transitory computer-readable storage medium. The storage medium stores computer instructions. When a computer reads the computer instructions from the storage medium, the computer executes the method of representative elementary volume (REV) cross-scale simulation for adaptive control in tunnel operations according to any one of the embodiments of the present disclosure.

Beneficial effects of the embodiments of the present disclosure include, but are not limited to:

In some embodiments of the present disclosure, only the failed finite elements are calculated using the discontinuous medium method, and the remaining finite elements are calculated using the continuous medium method. This saves a quantity of elements that require calculation by the discrete element method, reduces time required for traversal and calculation, and improves a calculation efficiency.

In some embodiments of the present disclosure, a volume of a finite element is a volume of a representative elementary volume model, i.e., a volume of an REV model. Constructing a full-region coverage rock mass model based on features of the representative elementary volume ensures a consistency of macroscopic mechanical properties and an accuracy of calculation results when calculation by the continuous medium method is converted to mesoscopic calculation by a discontinuous medium method.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering indicates the same structure, wherein:

FIG. 1 is a flowchart illustrating an exemplary method of representative elementary volume (REV) cross-scale simulation for adaptive control in tunnel operations according to some embodiments of the present disclosure;

FIG. 2 is a schematic diagram illustrating a method of representative elementary volume (REV) cross-scale simulation for adaptive control in tunnel operations according to some embodiments of the present disclosure;

FIG. 3 is a schematic diagram illustrating an exemplary rock mass engineering scale calculation model according to some embodiments of the present disclosure;

FIG. 4 is a schematic diagram illustrating discrete element model sampling according to some embodiments of the present disclosure;

FIG. 5 is a graph illustrating a relationship between a size of a discrete element model and a volumetric joint density according to some embodiments of the present disclosure;

FIG. 6 is a graph illustrating a relationship between a size of a discrete element model and a volumetric joint number according to some embodiments of the present disclosure;

FIG. 7 is a schematic diagram illustrating a rock mass model divided into a plurality of finite elements according to some embodiments of the present disclosure; and

FIG. 8 is a schematic diagram illustrating mesh division after a rock mass model is divided into a plurality of finite elements according to some embodiments of the present disclosure.

### DETAILED DESCRIPTION

In order to more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system,” “device,” “unit” and/or “module” used herein are a way to distinguish between different components, elements, parts, sections, or assemblies at different levels. However, the terms may be replaced by other expressions if other words accomplish the same purpose.

As shown in the present disclosure and in the claims, unless the context clearly suggests an exception, the words “one,” “a,” “an,” “one kind,” and/or “the” do not refer specifically to the singular, but may also include the plural. Generally, the terms “including” and “comprising” suggest only the inclusion of clearly identified steps and elements, however, the steps and elements that do not constitute an exclusive list, and the method or apparatus may also include other steps or elements.

Flowcharts are used in the present disclosure to illustrate the operations performed by a system according to embodiments of the present disclosure, and the related descriptions are provided to aid in a better understanding of the method and/or system. It should be appreciated that the preceding or following operations are not necessarily performed in an exact sequence. Instead, steps can be processed in reverse order or simultaneously. Also, it is possible to add other operations to these processes or to remove a step or steps from these processes.

As described above, when using the discrete element method for engineering-scale simulation calculations, a count of calculation particles may reach millions, tens of millions, or even more. This may inevitably lead to an exponential increase in required computing resources and time, while also posing a huge challenge to computing and analysis capabilities. To address the above problems, embodiments of the present disclosure provide a method of representative elementary volume (REV) cross-scale simulation for adaptive control in tunnel operations.

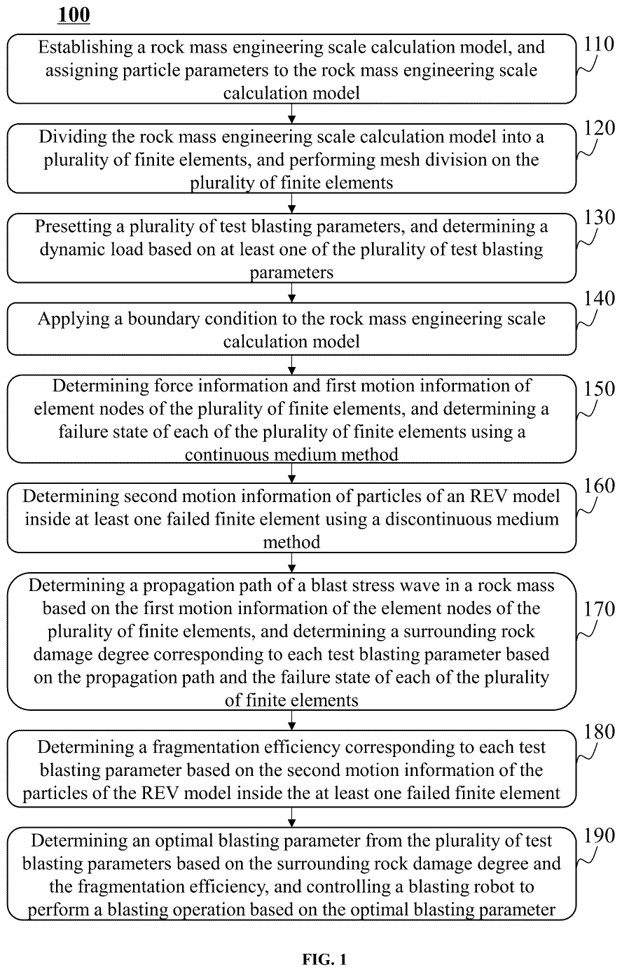

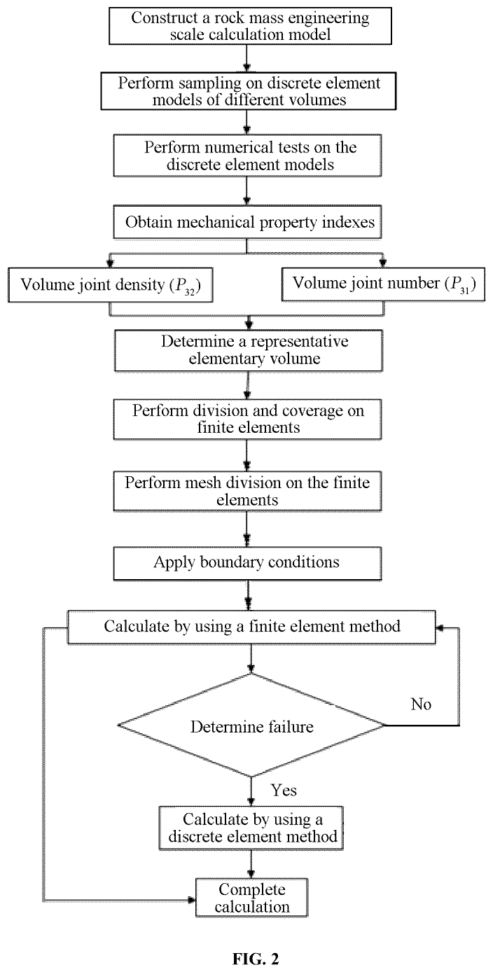

FIG. 1 is a flowchart illustrating an exemplary method of representative elementary volume (REV) cross-scale simulation for adaptive control in tunnel operations according to some embodiments of the present disclosure. As shown in FIG. 1, a process 100 includes following operations. In some embodiments, the process 100 may be executed by a processor. FIG. 2 is a schematic diagram illustrating a method of representative elementary volume (REV) cross-scale simulation for adaptive control in tunnel operations according to some embodiments of the present disclosure.

The processor may process data and/or information obtained from other devices or system components. The processor may execute program instructions based on the data, the information, and/or processing results to perform one or more functions described in the present disclosure. In some embodiments, the processor may include one or more sub-processing devices (e.g., a single-core processing device or a multi-core multi-chip processing device). Merely by way of example, the processor may include a central processing unit (CPU), a controller, a microprocessor, or any combination thereof. In some embodiments, the processor may include a plurality of modules. Different modules may be configured to execute different program instructions.

Operation 110, establishing a rock mass engineering scale calculation model, and assigning particle parameters to the rock mass engineering scale calculation model.

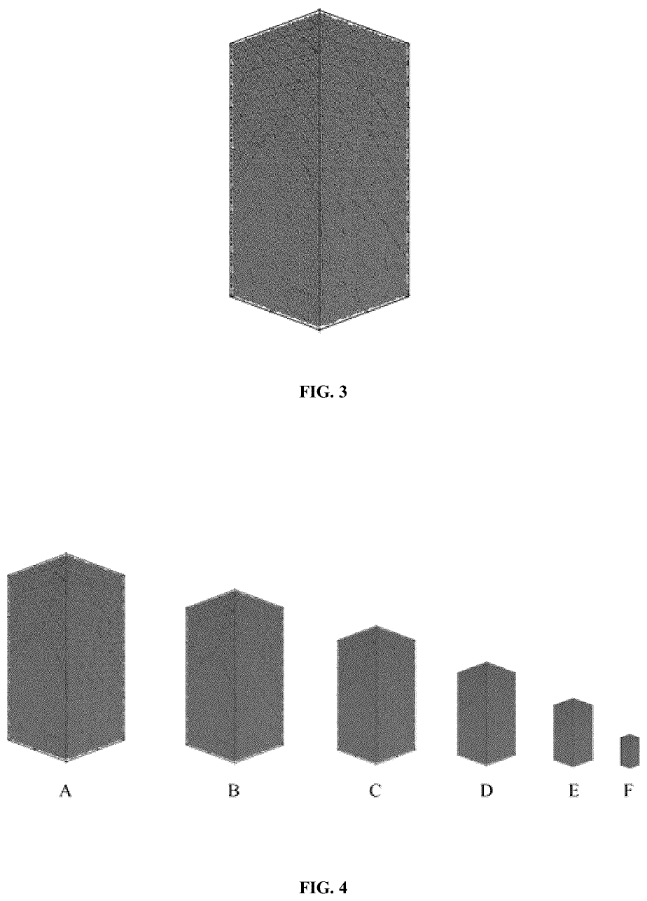

The rock mass engineering scale calculation model (hereinafter referred to as a rock mass model) refers to a calculation model composed of particles and having internal joints, used to simulate a mechanical behavior of a rock mass. The rock mass engineering scale calculation model is shown in FIG. 3. FIG. 3 is a schematic diagram illustrating an exemplary rock mass engineering scale calculation model according to some embodiments of the present disclosure.

In some embodiments, the processor may construct the rock mass model through a discrete element method (DEM). For example, the rock mass model may be composed of a series of interacting discrete particles (referred to as particles). The particles may be circular, spherical, polygonal, or polyhedral in shape.

In some embodiments, the processor may also set joints in the rock mass model composed of particles. For example, the joints may be simulated by setting weakened zones of contact bonds at predetermined positions or along specific directions. Contact parameters (e.g., a bond strength) of the weakened zones are lower than those of the rock mass matrix. As another example, a joint network may be explicitly preset in the rock mass model based on geological exploration data or statistical models, so that particles in the rock mass model have special contact properties along joint surfaces.

In some embodiments, the processor may also establish the rock mass model through methods such as a finite discrete element method or a hybrid element method.

In some embodiments, the processor may assign particle parameters to the rock mass engineering scale calculation model. The particle parameters include material parameters and the contact parameters.

In some embodiments, the material parameters include, but are not limited to, a density, a stiffness, a friction coefficient, a porosity, a particle size distribution, and the contact parameters include, but are not limited to, a normal stiffness, a tangential stiffness, the bonding stiffness, and a bonding spacing.

In some embodiments, the processor may determine and set the material parameters of the particles through experimental testing or a numerical calibration method. For example, macroscopic mechanical properties may be obtained by performing indoor physical and mechanical tests on rock mass samples. Then, an optimization algorithm may be used to inversely calibrate the macroscopic mechanical properties onto microscopic particle parameters such as the density, the stiffness, and the friction coefficient.

In some embodiments, the processor may determine and set the contact parameters between particles. For example, for a contact between particles in the rock mass model, a normal stiffness and a tangential stiffness of a contact point may be set based on mechanical properties of a particle material. As another example, for a contact simulating a joint surface, a low bonding stiffness and a small bonding spacing may be assigned to simulate a weakening or a fracture behavior of the joint.

Operation 120, dividing the rock mass engineering scale calculation model into a plurality of finite elements, and performing mesh division on the plurality of finite elements.

The finite element refers to a sub-region constituting the rock mass engineering scale calculation model. A volume of each of the plurality of finite elements is equal to a representative elementary volume (REV). The representative elementary volume refers to a minimum volume when a rock mass mechanical property index tends to be stable. For example, the representative elementary volume is a minimum representative volume that ensures that measured macroscopic mechanical properties (e.g., strength, deformation modulus, permeability, etc.) of a rock mass no longer change significantly with a change in a sample size.

In some embodiments, the processor may divide the rock mass model into the plurality of finite elements based on a geometric boundary and an internal feature of the rock mass model using a spatial discretization method to segment the rock mass model into independent sub-regions. For example, the rock mass model may be uniformly divided into a series of finite elements of equal size based on an overall geometric shape and a size of the rock mass model, and a volume of each finite element is set to the REV of the rock mass. As another example, when the rock mass model has significant geological structures (e.g., a large fault, a joint zone), the rock mass model may be divided non-uniformly based on geological features to ensure that each divided finite element has relatively consistent internal features, and a volume of each element equals or approximates the REV.

In some embodiments, the processor may also use a domain decomposition method to decompose a complex rock mass model into several sub-domains, or use an adaptive division strategy to obtain the plurality of finite elements, and ensure that a volume of each finite element equals the REV.

In some embodiments, a process for determining the REV includes: sampling the rock mass model according to a preset length-width-height ratio to establish a plurality of discrete element models having different sizes and an identical shape; performing a numerical test on each of the plurality of discrete element models respectively to obtain a variation log of a rock mass mechanical property index of the discrete element model; and determining a volume of a discrete element model when a target mechanical property index in the variation log of the rock mass mechanical property index tends to be stable as the REV.

The discrete element model refers to a rock mass model established by sampling from the rock mass model, constituted by discrete elements and used for the numerical test. The preset length-width-height ratio refers to a proportional relationship between a length, a width, and a height that is predetermined and used to guide a sampling process during model sampling. For example, the preset length-width-height ratio may be 1:1:1 or 2:1:1.

In some embodiments, the processor may extract a plurality of sub-regions from an established rock mass model according to the preset length-width-height ratio based on an overall geometric size of the rock mass model. FIG. 4 is a schematic diagram illustrating discrete element model sampling according to some embodiments of the present disclosure. Merely by way of example, as shown in FIG. 4, the processor may establish six discrete element models, labeled as a discrete element model A, a discrete element model B, a discrete element model C, a discrete element model D, a discrete element model E, and a discrete element model F from large to small. The discrete element models are consistent in shape but have a decreasing relationship in size. For example, discrete element models of different sizes may be generated by directly adjusting boundary sizes of a discrete element model, or by intercepting a same model at different scales.

The rock mass mechanical property index refers to a quantifiable parameter used to describe a mechanical behavior and a feature of a rock mass. In some embodiments, the rock mass mechanical property index includes a mechanical index, a deformation index, and a structural plane strength index. The mechanical index includes a uniaxial compressive strength, a triaxial compressive strength, or the like. The deformation index includes an elastic modulus, a Poisson's ratio, or the like. The structural plane strength index includes a volumetric joint density (P₃₂), a volumetric joint number (P₃₁), or the like. The structural plane strength index directly reflects a variation law of a structural plane system with size and is a most direct index for determining the REV. Therefore, in embodiments of the present disclosure, the volumetric joint density (P₃₂) and the volumetric joint number (P₃₁) may be selected as indices for determining a volume of an element, i.e., the target mechanical property index.

In some embodiments, the processor may use discrete element software to simulate each discrete element model to obtain the variation log of the rock mass mechanical property index of each discrete element model. A simulation content may include a uniaxial compression test, a triaxial compression test, a shear test, or the like. In some embodiments, during the numerical test, mechanical responses of each discrete element model under different loads or deformation conditions may be recorded and tracked, including a stress, a strain, a displacement, a joint cracking or a slip condition, and the data may be recorded to form the variation log.

In some embodiments, the processor may determine the target mechanical property index used for determining the REV.

The target mechanical property index refers to a specific rock mass mechanical property index selected for evaluating a trend of a rock mass mechanical property with size change when determining the REV. For example, the target mechanical property index may include the volumetric joint density and the volumetric joint number. The volumetric joint density and the volumetric joint number may be directly obtained based on the variation log of the rock mass mechanical property index of the discrete element model. The volumetric joint density may quantify a total area of joint surfaces per unit volume, and the volumetric joint number counts a quantity of joints per unit volume. By selecting the volumetric joint density and the volumetric joint number as the target mechanical property index, a variation law of a rock mass structural plane system with size may be directly and accurately reflected, thereby significantly improving an accuracy of subsequent simulation of mechanical behavior of the rock mass engineering scale calculation model.

In some embodiments, the target mechanical property index may also be determined in other ways. For example, a most sensitive or most important mechanical property may be selected as the target mechanical property index based on an engineering focus or a rock mass feature. As another example, the target mechanical property index may be selected by performing a preliminary analysis on a plurality of indices and selecting an index with a most obvious variation trend at different scales.

A minimum volume of a discrete element model when the target mechanical property index tends to be stable may be determined as the REV, i.e., the REV corresponding to the finite element. When a rock mass volume is less than the REV, a rock mass mechanical property varies with the volume; when the rock mass volume is greater than the REV volume, the rock mass volume may be regarded as an equivalent continuous medium with the REV as a basic unit.

In some embodiments, the processor may determine a volume of a discrete element model, at which a difference between a rate of change of the target mechanical property index in the variation log of the rock mass mechanical property index and 0 is not greater than a stability threshold, as the rREV. The stability threshold may be preset based on experience.

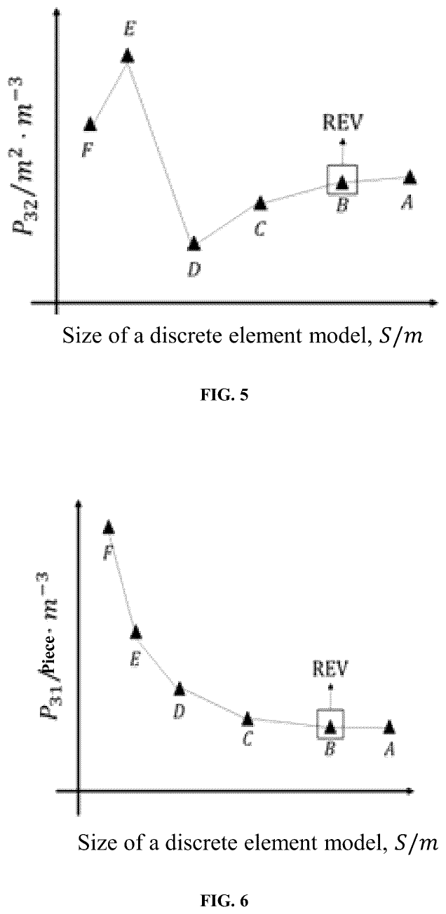

In some embodiments, the processor may plot a curve of the target mechanical property index (such as the volumetric joint density or the volumetric joint number) versus a size of the discrete element model. Merely by way of example, as shown in FIGS. 5-6, curves of the volumetric joint density (P₃₂) and the volumetric joint number (P₃₁) for six discrete element models are plotted. A horizontal coordinate represents the size of the discrete element model, and a vertical coordinate represent the volumetric joint density (P₃₂) or the volumetric joint number (P₃₁), respectively. Starting from the discrete element model B among the six discrete element models, the volumetric joint density (P₃₂) and the volumetric joint number (P₃₁) of the discrete element models begin to stabilize. Therefore, a volume of the discrete element model B is the REV.

In some embodiments, the processor may also perform numerical fitting on data of the variation log to calculate a derivative of the target mechanical property index with respect to the size. When an absolute value of the derivative is less than the stability threshold, a size of a corresponding discrete element model is the REV.

In some embodiments of the present disclosure, by establishing a plurality of discrete element models with different sizes and the identical shape to perform the numerical test, the variation log of the rock mass mechanical property index is obtained. Based on a model volume when the rate of change of the target mechanical property index tends to stabilize, the REV is determined. This approach may accurately capture a variation law of rock mass mechanical properties with scale, thereby scientifically determining the REV, thereby avoiding errors from subjective judgment in traditional methods and improving an accuracy and reliability of selecting macroscopic mechanical parameters in numerical simulation of rock mass engineering.

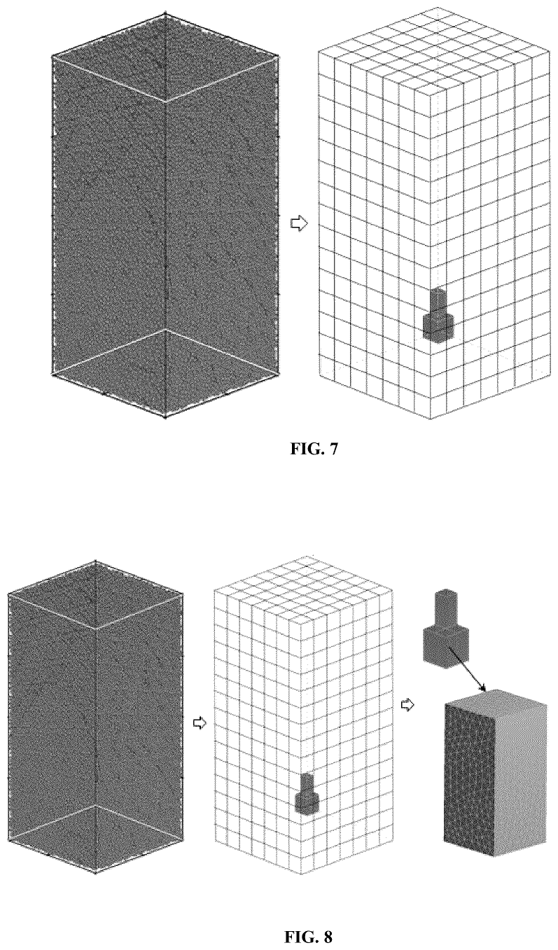

In some embodiments, as shown in FIG. 7 and FIG. 8, the processor may divide an entire rock mass model into a plurality of finite elements with REV attributes based on the REV. The processor may perform the mesh division on the finite elements, i.e., the finite elements are used to achieve full-area coverage of the rock mass engineering scale calculation model.

Dividing a volume of the finite elements into a minimum volume of a discrete element model when the rock mass mechanical property index tend to stabilize, i.e., the REV, may characterize physical and mechanical properties of a rock mass, ensuring an accuracy when the finite elements perform calculations using a discontinuous medium method.

In some embodiments, the processor may use mesh generation technology to discretize each finite element into smaller, interconnected geometric elements, i.e., mesh cells. For example, for a finite element with a regular shape, a structured mesh division technique may be used to generate mesh cells composed of regular shapes such as quadrilaterals (two-dimensional) or hexahedrons (three-dimensional) to ensure mesh quality and computational efficiency. As another example, for a finite element with an irregular shape or having complex internal structures, an unstructured mesh division technique may be used to generate mesh cells composed of irregular shapes such as triangles (two-dimensional) or tetrahedrons (three-dimensional) to better adapt to complex geometric boundaries and internal features.

In some embodiments, the processor may also use an adaptive mesh refinement technique to dynamically adjust the mesh density during a calculation process based on results such as stress and strain gradients. The processor may also use a hybrid mesh division technique, combining advantages of structured and unstructured meshes to apply different strategies to different regions.

Operation 130, presetting a plurality of test blasting parameters, and determining a dynamic load based on at least one of the plurality of test blasting parameter.

The test blasting parameter refers to a combination of parameters used to simulate and evaluate a blasting effect. For example, the test blasting parameter may include an explosive type, a charge amount, a blasting hole position, and a detonation sequence. The explosive type refers to a type of blasting agent selected, such as an emulsion explosive or TNT, which mainly affects a detonation velocity (energy release) of the explosive. The blasting hole position refers to a position of a blasting hole pre-drilled on a surface of a rock mass. The charge amount refers to a total mass of explosive loaded in a single blasting hole, which affects a peak pressure generated by an explosion. The detonation sequence refers to a time sequence of detonation of explosives in each blasting hole position.

In some embodiments, the processor may preset the plurality of test blasting parameters by defining parameter combinations based on engineering experience and historical data. For example, different explosive types, charge amounts (e.g., 5 kg, 10 kg, 15 kg per hole position), blasting hole positions (e.g., a varying hole spacing, a minimum burden), and detonation sequences (e.g., a millisecond delay) may be set. In some embodiments, the processor may also preset the plurality of test blasting parameters through theoretical calculation or preliminary small-scale field tests. For example, for a specific rock mass type, different explosive types are selected, and features of the rock mass type (such as a detonation velocity) are incorporated into parameter settings.

In some embodiments, the plurality of test blasting parameters may also be preset in various other ways. For example, the plurality of test blasting parameters may be randomly generated within a reasonable range, or optimized through an intelligent algorithm based on a desired blasting effect.

The dynamic load refers to a boundary pressure condition applied to nodes of the rock mass model that varies over time. For example, a mathematical expression form of the dynamic load may be a pressure-time curve.

The pressure-time curve is used to simulate a variation of pressure acting on a rock mass over time during an explosion process. For example, the larger the charge amount, the higher the pressure peak. The faster the detonation velocity of an explosive, the steeper the rising segment of the curve, i.e., the more intense the explosion shock.

In some embodiments, the processor may use empirical formulas in blasting mechanics or explosion load functions to convert each test blasting parameter into pressure-time curves at a plurality of detonation points, thereby obtaining the dynamic load. For example, a specific formula considering a charge mass, a blasting distance, and properties of a rock mass may be applied to calculate pressure endured by the rock mass over time at different detonation point positions. As another example, advanced numerical methods, such as an arbitrary Lagrangian-Eulerian method or a coupled Eulerian-Lagrangian technique, may be used to simulate an explosive detonation process, directly generating pressure-time curves at selected point locations.

In some embodiments, the dynamic load may also be determined in various other ways. For example, the dynamic load may be obtained from scaled model tests, or predicted by integrating a machine learning model.

Operation 140, applying a boundary condition to the rock mass engineering scale calculation model.

In some embodiments, the boundary condition may be determined according to a construction site situation and may be consistent with an on-site construction situation. For example, an initial stress boundary condition and a displacement constraint boundary condition of the rock mass engineering scale calculation model may be determined based on data such as an on-site geological exploration report, a rock mass initial stress test result, a groundwater burial depth, or the like.

In some embodiments, the processor may also use a previously determined dynamic load as a boundary condition, i.e., apply a corresponding pressure value to an element node of a finite element at a corresponding blasting initiation point position at a corresponding time to complete dynamic boundary load input. For example, when simulating a blasting operation, the pressure-time curve determined by the test blasting parameter may be applied as the dynamic load to nodes around a blasting hole.

Operation 150, determining force information and first motion information of element nodes of the plurality of finite elements, and determining a failure state of each of the plurality of finite elements using a continuous medium method.

The element node refers to a discrete point in a finite element used for calculating and transmitting mechanical information. The element node may serve as a node for finite element calculation.

The force information refers to information describing a state and composition of a force acting on the element node. For example, the force information may include a node resultant force, a node external force, a node deformation force, and a damping force.

The first motion information refers to physical quantity information describing a motion state of the element node. For example, the first motion information may include a node acceleration, a node speed, and a node displacement (e.g., a node displacement increment and a node total displacement).

The failure state refers to a state of whether a finite element undergoes a failure (including a shear failure or a tensile failure), and the failure state may be determined by judging whether the finite element satisfies a shear failure condition or a tensile failure condition. In some embodiments, the processor may determine a stress state of the finite element and judge whether the stress state of the finite element satisfies the shear failure condition or the tensile failure condition. The stress state of the finite element refers to a distribution of internal forces caused by forces and deformations borne inside the finite element. For example, the stress state of the finite element may be described by mechanical indices such as a maximum principal stress and a minimum principal stress of the finite element and may be tracked and calculated in real time by finite element analysis software.

In some embodiments, the continuous medium method employs an existing finite element method. The element node serves as a node for the finite element calculation, the processor may perform finite element analysis calculation on the entire rock mass model, track the stress state of each finite element in real time, and each finite element performs stress-strain calculation according to Hooke's law. For example, the processor may simulate a mechanical behavior of the entire rock mass model by executing pre-programmed finite element analysis software. At each calculation time step, the processor may calculate and update a stress tensor and a strain tensor of the finite element based on a deformation and a material constitutive relationship of the finite element.

In some embodiments, the force information of the element node (i.e., the node resultant force) may be obtained by calculating the node external force, the node deformation force, and the damping force. For example, a calculation formula (1) for the node resultant force is as follows:

$$F = {P}_{e} + {P}_{d} + {P}_{c} \qquad ( 1 )$$

where, F denotes the node resultant force; Pₑ denotes the node external force; P_{d} denotes the node deformation force (contributed by an element stress); P_{c} denotes the damping force.

In some embodiments, the first motion information of the element node may include the node acceleration, the node speed, the node displacement increment, and the node total displacement. The node acceleration may be obtained by calculating the node resultant force and a node mass. The node speed may be obtained by calculating the node acceleration and a calculation time step. The node displacement increment may be obtained by calculating the node speed and the calculation time step. The node total displacement may be obtained by calculating the node displacement increment and the calculation time step. For example, a calculation formula (2) for the first motion information is as follows:

$$a = F / m , v = \sum a Δ t , Δ u = v Δ t , u = \sum Δ t \qquad ( 2 )$$

where, a denotes the node acceleration; v denotes the node speed; Au denotes the node displacement increment; u denotes the node total displacement; m denotes the node mass; Δt denotes the calculation time step. An explicit solving process of finite element may be implemented based on alternate calculations of the formula (1) and the formula (2).

In some embodiments, an incremental method is used to calculate the element stress and the node deformation force, and by updating a strain matrix and node coordinates in real time, transmission of information between adjacent nodes may be achieved, enabling calculation of finite element large displacement and large deformation problems.

The above processes are all calculation processes of an existing finite element method and may be automatically performed using the finite element analysis software.

In some embodiments, after performing the finite element calculation on the first motion information and the force information of the element nodes of all finite elements, the processor determines the failure state of each finite element by judging whether each finite element undergoes the shear failure or the tensile failure.

In some embodiments, the processor may use a Mohr-Coulomb criterion and a maximum tensile stress criterion to judge whether each finite element undergoes the shear failure or the tensile failure.

In some embodiments, for each finite element, the processor may determine the compressive stress f^{s}, the tensile stress f^{t}, and the shear stress h on the finite element. The stress state of the finite element may be reflected by the compressive stress f^{s}, the tensile stress f^{t}, and the shear stress h.

For example, the processor may determine the compressive stress f^{s}, the tensile stress f^{t}, and the shear stress h according to a formula (3):

$$\{ \begin{matrix}{f}^{s} = {σ}_{1} - {σ}_{3} {N}_{φ} + 2 c \sqrt{{N}_{φ}} \\ {f}^{t} = {σ}_{3} - T \\ h = {f}^{t} + {α}^{p} ( {σ}_{1} - {σ}^{p} )\end{matrix} \qquad ( 3 )$$

where,

$${N}_{φ} = \frac{1 + sin φ}{1 - sin φ} , {α}^{p} = \sqrt{1 + {N}_{φ}^{2}} + {N}_{φ} , {σ}^{p} = {TN}_{φ} - 2 c \sqrt{{N}_{φ}} .$$

σ₁ denotes the maximum principal stress of the finite element, and σ₃ denotes the minimum principal stress of the finite element, which may be determined based on the force information of the element nodes calculated by the finite element method. The finite element software may automatically solve for the minimum principal stress and the maximum principal stress, and a solving process is not described in detail herein. c, φ, T denote a cohesion, an internal friction angle, and a tensile strength, respectively, which may be predetermined through experimental calculation based on material parameters adopted by the rock mass model. f^{s} denotes the compressive stress on the finite element, f^{t} denotes the tensile stress on the finite element, and h denotes the shear stress on the finite element.

In some embodiments, in response to the stress state of the finite element satisfying the shear failure condition, i.e., f^{s}≤0 and h≤0 (indicating no compression or in a tensile state), the finite element is determined to undergo the shear failure. This determination manner is used to identify a brittle behavior where the rock mass may undergo sudden failure due to shear action under low confining pressure or tensile environments.

In some embodiments, in response to the stress state of the finite element satisfying the tensile failure condition, i.e., f^{t}≥0 and h≥0 (indicating in the tensile state), the finite element is determined to undergo the tensile failure. This determination manner is used to identify brittle failure forms such as sudden cracking that may occur in the rock mass under tensile and specific shear coupling effects.

In some embodiments, the processor may also adopt other rock mass mechanical failure criteria to determine the failure state of the finite element, such as a Hoek-Brown criterion, a Drucker-Prager criterion, or the like.

In some embodiments of the present disclosure, by utilizing the Mohr-Coulomb criterion and the maximum tensile stress criterion to determine a shear or tensile failure state of each finite element, potential failure zones and failure modes of the rock mass model may be accurately identified, significantly improving the accuracy of failure prediction in numerical simulation of complex rock mass engineering, and providing a refined basis for engineering design and stability assessment.

In some embodiments, the processor may determine a maximum speed of particles of an REV model (also referred to as REV model particles) inside the at least one failed finite element based on the second motion information of the particles of the REV model inside the at least one failed finite element; in response to the maximum speed being lower than a preset speed threshold, mark the at least one failed finite element as an equivalent finite element; and, in response to an acceleration of an element node of a finite element corresponding to the equivalent finite element exceeding a preset acceleration threshold, mark the equivalent finite element as a failed finite element. For more content about the second motion information, the REV model, and the failed finite element, please refer to operation 160 and related descriptions thereof.

In some embodiments, the processor may, in a failed finite element, directly obtain a maximum value among current speed magnitudes of all REV model particles inside the failed finite element through the rock mass model, and designate the maximum value as the maximum speed of the failed finite element. For example, the processor may traverse all particles inside the failed finite element, determine a magnitude of a current velocity vector of each particle, and select a maximum value from magnitudes of all the particles as a particle maximum speed of the finite element.

The preset speed threshold refers to a speed critical value used to determine whether a particle system enters a stable static state, which is usually preset based on experience.

The equivalent finite element refers to a finite element that has failed but whose internal particles have entered a stable accumulation state.

In some embodiments, when detecting that a maximum speed of internal REV model particles of a failed finite element is lower than the preset speed threshold (e.g., lower than 0.001 m/s), it is determined that internal particles of the failed finite element have entered a static accumulation state. At this time, a dynamic calculation process of the internal particles of the finite element may be suspended, and the finite element may be marked as the “equivalent finite element”, and motion information of the internal particles is no longer continuously calculated, to reduce a calculation load and computing resource consumption during a simulation process.

The preset acceleration threshold refers to an acceleration critical value used to determine whether the equivalent finite element is subjected to external disturbance or stress influence, which is usually preset based on experience.

The acceleration of the element node of the finite element refers to an acceleration of any node of the finite element (e.g., a finite element may include eight nodes).

In some embodiments, if an acceleration of any node in the equivalent finite element exceeds the preset acceleration threshold (e.g., an absolute value of an acceleration of a node exceeds 5 m/s²), it is determined that the corresponding region is subjected to external disturbance or stress influence, and fine calculation needs to be resumed. At this time, the equivalent finite element is marked as the “failed finite element” again, and the motion information of the internal particles of the equivalent finite element is continuously calculated again (i.e., re-enabling a dynamic calculation process of the internal particles of the equivalent finite element).

In some embodiments of the present disclosure, by introducing the judgment based on the particle maximum speed threshold, the failed finite element whose internal particles tend to be stable is dynamically marked as the equivalent finite element to suspend a dynamic calculation of the internal particles of the failed finite element. Meanwhile, by monitoring the acceleration of the element node, a real-time wake-up mechanism for the equivalent finite element is implemented. This may significantly reduce the calculation load of the rock mass engineering scale calculation model during simulation of complex dynamic processes such as blasting, while ensuring that fine calculation is resumed at critical moments, improving the accuracy of simulation results.

Operation 160, determining the second motion information of particles of the REV model inside the at least one failed finite element using the discontinuous medium method.

In some embodiments, for each failed finite element, the processor may use the discontinuous medium method to determine the second motion information and the force information of particles of the REV model inside the failed finite element.

The particle refers to a basic constituent unit constituting the rock mass model or the REV model. The second motion information refers to motion information of the particle, such as a speed and a displacement of the particle.

In some embodiments, the discontinuous medium method employs a discrete element method.

In some embodiments, the processor may calculate a speed and a displacement of a particle (i.e., a to-be-calculated particle) inside the at least one failed finite element using an interpolation method based on speeds and displacements of element nodes of the plurality of finite elements.

In some embodiments, the processor may select 2-3 element nodes, which are closest to the to-be-calculated particle, from the element nodes of the plurality of finite elements, and perform an interpolation calculation to obtain the displacement and the speed of the to-be-calculated particle, to save a calculation time. For example, during the interpolation calculation, to save the calculation time and ensure a local accuracy, a position of the to-be-calculated particle in a finite element mesh may be first identified, and then only 2-3 element nodes of the finite elements closest to a spatial position of the particle may be selected (e.g., determined by Euclidean distance).

In some embodiments, the processor may determine the speed of the to-be-calculated particle according to a formula (4):

$${v}^{p} = {\sum }_{j = 1}^{{N}_{e}} {W}_{j} {v}_{j}^{e} \qquad ( 4 )$$

where, v^{p} denotes the speed of the to-be-calculated particle, Wⱼ denotes an interpolation coefficient of an j-th element node of the finite element used for interpolation calculation,

$${v}_{j}^{e}$$

denotes a speed of the j-th element node used for the interpolation calculation, and Nₑ denotes a count of element nodes used for the interpolation calculation.

In some embodiments, the processor may determine the displacement of the to-be-calculated particle according to a formula (5):

$${u}^{p} = {\sum }_{j = 1}^{{N}_{e}} {W}_{j} {u}_{j}^{e} \qquad ( 5 )$$

where, u^{p} denotes the displacement of the to-be-calculated particle, Wⱼ denotes the interpolation coefficient of the j-th element node of the finite element used for the interpolation calculation,

$${u}_{j}^{e}$$

denotes a displacement of the j-th element node used for the interpolation calculation, and Nₑ denotes the count of element nodes used for the interpolation calculation.

In some embodiments, the process for calculating force information of a particle inside an element employs an existing method for calculating force information of a particle in the discrete element method, which is not described in detail herein.

In some embodiments of the present disclosure, by utilizing the speed and the displacement of the element node and adopting the interpolation method to accurately determine the speed and the displacement of the particle inside the failed finite element, and in particular, by selecting the closest 2-3 element nodes for the interpolation to balance an efficiency and accuracy, it enables further analysis of motion behaviors and failure mechanisms of particles at a microscopic level of a rock mass after macroscopic failure occurs, significantly improving a refinement degree of numerical simulation, providing key data for understanding particle response of the rock mass under blasting action, and having important significance for optimizing blasting parameters and preventing engineering hazards.

In some embodiments of the present disclosure, through the process 100, a FEM-REV-DEM cross-scale calculation method spanning engineering scale, macroscopic scale, and mesoscopic scale may be established, enabling simulation calculation of models with millions or tens of millions of particles. Compared with a traditional purely discontinuous medium method, the embodiment of the present disclosure only performs calculation using the discontinuous medium method on the failed finite element, reducing time required for traversal and calculation by the discontinuous medium method, and greatly improving a calculation efficiency. In the calculation method of the embodiment of the present disclosure, the volume of the finite element is the REV, by constructing a full-area coverage rock mass model based on features of the REV, it ensures consistency of macroscopic mechanical properties and accuracy of calculation results when calculation by the continuous medium method is converted to mesoscopic calculation by the discontinuous medium method.

The calculation method in embodiments of the present disclosure may simulate macroscopic deformation of the rock mass model through the finite element method, and may simulate smaller-scale fracture of the rock mass model through the discrete element method, resulting in diverse simulation results.

Operation 170, determining a propagation path of a blast stress wave in the rock mass based on the first motion information of the element nodes of the plurality of finite elements, and determining a surrounding rock damage degree corresponding to each test blasting parameter based on the propagation path and the failure state of each of the plurality of finite elements.

The propagation path refers to a trajectory or route of propagation of the blast stress wave in the rock mass. For example, the propagation path may be obtained by tracking spatial positions where peak accelerations of element nodes of the finite elements appear at different times and performing spatial connection of the spatial positions.

In some embodiments, the processor may run the rock mass model to directly obtain a speed, an acceleration, a displacement increment, and an accumulated displacement of each element node corresponding to each finite element at each time (i.e., obtain the first motion information of the element node), thereby obtaining the propagation path. For example, explicit dynamic analysis of the model may be performed using the finite element analysis software to output the speed, the acceleration, and the displacement information (i.e., the first motion information) of each element node at each calculation time step. After obtaining the first motion information, by tracking spatial positions where peak accelerations of element nodes appear at different times and connecting these spatial positions, the propagation path of the blast stress wave in the rock mass may be obtained.

In some embodiments, the processor may determine the propagation path by analyzing a propagation trajectory of a stress wave front (e.g., a maximum principal stress wave front) or by calculating an energy propagation trajectory.

The surrounding rock damage degree refers to a quantitative index reflecting the integrity of retained rock mass (i.e., a part that does not need to be excavated).

The failure state of the finite element refers to a judgment result of whether the finite element undergoes the shear failure or the tensile failure, which may be obtained based on the Mohr-Coulomb criterion and the maximum tensile stress criterion.

In some embodiments, the processor may, according to a preset contour line (i.e., a contour line requiring excavation), count a proportion of a quantity of finite elements whose failure state is determined as “failed” among finite elements located in a region outside the contour line to a total quantity of the finite elements in the region, as the surrounding rock damage degree. For example, a three-dimensional geometric body representing a future excavation boundary (i.e., the preset contour line) may be first defined in the rock mass model, and then all finite elements located outside the contour line may be identified. Further, these external finite elements may be traversed, the quantity of the finite elements marked as “failed” according to the shear failure condition or the tensile failure condition may be counted, and the quantity may be compared with the total quantity of the finite elements in the external region to calculate the surrounding rock damage degree.

Operation 180, determining a fragmentation efficiency corresponding to each test blasting parameter based on the second motion information of the particles of the REV model inside the at least one failed finite element.

The fragmentation efficiency refers to a quantitative index reflecting a fragmentation degree of a rock mass to be excavated (i.e., a part that needs to be excavated).

The second motion information may be obtained by explicit calculation of the speed and displacement of particles inside the failed finite element using the discontinuous medium method, reflecting a separation degree and a fragmentation feature between the particles.

In some embodiments, the processor may count failed finite elements located in the region inside the contour line, and count a fracture proportion of bonding bonds between internal particles of REV models of the failed finite elements as the fragmentation efficiency. For example, a to-be-excavated region inside the preset contour line may first be defined in the rock mass model, and then all finite elements located in the region which are already determined as failed (i.e., failed finite elements) may be identified. For these failed finite elements, the second motion information of internal particles of REV models of the failed finite elements may be obtained, and according to the second motion information, a proportion of a quantity of already fractured bonding bonds among all bonding bonds between the particles to a total quantity of bonding bonds may be counted, the proportion being the fragmentation efficiency. Fracture of a bonding bond refers to a situation where the stress borne by the bonding bond exceeds a preset bonding stiffness, at which point the bonding bond fractures. The fracture proportion of bonding bonds may be obtained by statistics from the rock mass model.

Operation 190, determining an optimal blasting parameter from the plurality of test blasting parameters based on the surrounding rock damage degree and the fragmentation efficiency, and controlling a blasting robot to execute the blasting operation based on the optimal blasting parameter.

In some embodiments, the processor may test the plurality of test blasting parameters, screen out a test blasting parameter with a lowest surrounding rock damage degree and a fragmentation efficiency higher than a preset threshold from the plurality of test blasting parameters, and determine the test blasting parameter as the optimal blasting parameter. For example, simulation calculation may be performed for each test blasting parameter, and a surrounding rock damage degree and a fragmentation efficiency corresponding to the test blasting parameter may be obtained respectively. Then, a minimum requirement for the fragmentation efficiency (the preset threshold) may be set, all test blasting parameters satisfying the preset threshold may be screened out, and from the all test blasting parameters satisfying the preset threshold, a test blasting parameter with the smallest surrounding rock damage degree may be selected as the optimal blasting parameter.

In some embodiments, the optimal blasting parameter includes an optimal explosive type, an optimal charge amount, an optimal blasting hole position, and an optimal detonation sequence.

In some embodiments, controlling the blasting robot to execute the blasting operation includes: controlling the blasting robot to load an explosive into the optimal blasting hole position based on the optimal explosive type and the optimal charge amount; and detonating the explosive based on the optimal detonation sequence to complete a blasting task for the rock mass.

In some embodiments, the processor may transmit the determined optimal blasting parameter to a control system of the blasting robot. For example, the optimal blasting parameter may be sent to the blasting robot via wired or wireless communication. After receiving the optimal blasting parameter, the blasting robot may complete a series of blasting operation steps such as drilling, charging, and detonation.

In some embodiments, after receiving the optimal blasting parameter, the control system of the blasting robot selects a corresponding explosive module according to the optimal explosive type, precisely measures the amount of the explosive according to the optimal charge amount, and loads the explosive into a predetermined optimal blasting hole position via a mechanical arm. A navigation and sensing system of the blasting robot guides the blasting robot to precisely locate the optimal blasting hole position, ensuring accurate and safe loading of the explosive. In some embodiments, the blasting robot may also complete the selection, measurement, and loading operations of the explosive through other automated or semi-automated manners.

In some embodiments, the blasting robot controls a detonator or a detonator system according to the optimal detonation sequence to detonate the explosive in each blasting hole according to a predetermined time interval and order. The blasting robot may, after confirming that personnel and equipment are at a safe distance, trigger the detonation system via a safe communication manner to ensure accurate detonation according to the optimal detonation sequence, thereby completing the blasting task for the rock mass. In some embodiments, the detonation process may also be completed collaboratively by the blasting robot and a remote control center, with the robot responsible for on-site preparation and the remote center responsible for issuing a final detonation instruction.

In some embodiments of the present disclosure, by determining the propagation path of the blast stress wave based on the first motion information of element nodes of the finite elements, quantifying the surrounding rock damage degree by combining the propagation path and element failure states, and calculating the fragmentation efficiency based on the second motion information of particles inside failed elements, further by determining the optimal blasting parameter based on the surrounding rock damage degree and the fragmentation efficiency and guiding the blasting robot to execute the operation, refined prediction and control of blasting effects are achieved, significantly improving the safety, controllability, and efficiency of blasting construction. By controlling the blasting robot to execute the blasting operation based on the optimal explosive type, the optimal charge amount, the optimal blasting hole position, and the optimal detonation sequence, precise application of blasting parameters and automated construction are realized. This significantly improves the safety, accuracy, and efficiency of the blasting operation, effectively reduces risks of manual operation, and optimizes blasting effects.

In some embodiments, the processor may determine an average stress of element nodes of a plurality of finite elements in a first region based on the force information of the element nodes of the plurality of finite elements; determine a target thrust cylinder pressure and a target cutterhead rotation speed based on the average stress of the element nodes of the plurality of finite elements in the first region; control a tunnel boring machine to advance toward the first region based on the target thrust cylinder pressure, and to cut a rock mass in the first region based on the target cutterhead rotation speed.

The first region refers to a to-be-excavated region ahead of the tunnel boring machine. The first region corresponds to a plurality of finite elements covered by a to-be-excavated path in the rock mass model.

In some embodiments, the processor may select a preset count of element nodes of the plurality of finite elements distributed along a tunneling direction (i.e., corresponding to the first region). The processor may further obtain the force information of the element node of each finite element using the continuous medium method, and perform averaging on the force information of the element node of each finite element to obtain the average stress. The average stress is used to characterize a current rock mass resistance. For more content about obtaining the force information of the element node, please refer to operation 150.

The target thrust cylinder pressure and the target cutterhead rotation speed refer to expected or calculated operating parameters set for the tunnel boring machine for thrusting and cutting the rock mass during a tunneling operation, respectively. For example, the target thrust cylinder pressure indicates a thrust required for the tunnel boring machine to overcome a rock mass resistance. The target cutterhead rotation speed indicates a rotation speed of a cutterhead for cutting the rock mass.

In some embodiments, the processor may determine the target thrust cylinder pressure and the target cutterhead rotation speed using a preset empirical mapping relationship between the average stress and control parameters. For example, if the average stress is relatively large (indicating a relatively strong rock mass resistance), a relatively high thrust cylinder pressure needs to be set to overcome the rock mass resistance, and the rotation speed of the cutterhead may be appropriately reduced to avoid equipment damage caused by excessive cutting. Conversely, if the average stress is relatively small (indicating a relatively soft rock mass), the thrust cylinder pressure may be appropriately reduced, and the rotation speed of the cutterhead may be increased to improve tunneling efficiency. As another example, a specific numerical correspondence relationship between the average stress and the control parameters may be set through a preset empirical mapping curve. For example, a piecewise linear function may be used to map an average stress interval to a target thrust cylinder pressure and a target cutterhead rotation speed corresponding to the average stress.

In some embodiments, the processor may also use artificial intelligence algorithms based on fuzzy logic, neural networks, or the like, to intelligently determine or adjust the target thrust cylinder pressure and the target cutterhead rotation speed according to a real-time average stress value.

In some embodiments, the processor may transmit the determined target thrust cylinder pressure and the determined target cutterhead rotation speed to a control system of the tunnel boring machine. After receiving the target thrust cylinder pressure and the target cutterhead rotation speed, the control system of the tunnel boring machine drives a thrust cylinder of the boring machine to apply a corresponding pressure, causing the tunnel boring machine to move forward stably. Simultaneously, the control system drives a cutterhead motor to rotate at the set rotation speed, thereby efficiently cutting the rock mass in the first region. An automated control module inside the tunnel boring machine continuously monitors an actual thrust cylinder pressure and an actual cutterhead rotation speed and performs closed-loop control to ensure that the actual thrust cylinder pressure and the actual cutterhead rotation speed comply with the target thrust cylinder pressure and the target cutterhead rotation speed.

In some embodiments of the present disclosure, the average stress is determined based on the force information of the element nodes of the finite elements in the to-be-excavated region. The thrust cylinder pressure and the cutterhead rotation speed of the tunnel boring machine are adaptively adjusted based on the average stress. This achieves a linkage between rock mass resistance perception and equipment control, significantly improves the tunneling efficiency, reduces an energy consumption and an equipment damage risk, and enhances the safety and controllability of tunnel boring operations.

In some embodiments, the processor may: obtain a second region; in response to a failure state of at least one finite element in the second region satisfying the shear failure condition: determine a drilling depth based on a distribution of at least one failed finite element in the second region; control a drilling machine to perform drilling based on the drilling depth to release pressure; determine a quantity proportion of high-stress finite elements based on force information of element nodes of the at least one failed finite element in the second region; determine a rock bolt density based on the quantity proportion of the high-stress finite elements; determine an installation quantity based on the rock bolt density and an excavation face cross-sectional area; and control a rock bolt jumbo to install the installation quantity of rock bolts for support.

The second region refers to an excavated region behind the tunnel boring machine. The second region corresponds to a surrounding rock region after excavation units in the rock mass model are removed. The second region may include finite elements covered by a tunnel crown, sidewalls, and a floor. The second region may be determined according to a current excavation situation.

The shear failure condition refers to a condition to judge whether a stress state of a finite element satisfies the shear failure. For more content about the stress state of the finite element, please refer to operation 150. The shear failure condition may include f^{s}≤0 and h≤0.

In some embodiments, the processor may monitor a stress state of each finite element in the second region in real time, and determine, according to a calculation result of operation 150, whether the failure state of each finite element in the second region satisfies the shear failure condition.

The drilling depth refers to a depth to which a drill hole extends.

In some embodiments, the processor may determine a maximum continuous distribution depth of the failed finite elements in the second region in space as a corresponding drilling depth. This ensures that the drill hole may penetrate a shear failure zone to achieve surrounding rock pressure release. For example, the processor identifies all finite elements that have undergone the shear failure, and analyzes a continuous distribution range of the finite elements in a vertical or radial direction to find a deepest or farthest failure point.

In some embodiments, the processor may transmit the determined drilling depth to a control system of the drilling machine, causing the drilling machine to perform a drilling operation automatically or semi-automatically. For example, after receiving the drilling depth parameter, a propulsion mechanism and a drill rod feed stroke of the drilling machine are precisely controlled. This ensures that a drill bit may penetrate the shear failure zone to achieve surrounding rock stress release. As another example, a sensor on the drilling machine monitors the drilling depth and a state inside the drill hole in real time. The sensor feeds data back to the control system to ensure the accuracy and safety of the drilling operation.

The high-stress finite element refers to a finite element whose maximum principal stress exceeds a preset stress threshold. The preset stress threshold may be preset based on a rock mass material or an empirical safety factor.

In some embodiments, the processor may: count a quantity of finite elements (i.e., high-stress finite elements) whose maximum principal stress exceeds the preset stress threshold, among the finite elements that have undergone the shear failure in the second region. The processor may further use a proportion of the quantity of the high-stress finite elements to a total quantity of the finite elements that have undergone the shear failure as the quantity proportion of the high-stress finite elements. For example, after calculating the force information of the element node, the finite element analysis software automatically solves a maximum principal stress of each finite element. The processor may traverse the finite elements that have undergone the shear failure, screen out the high-stress finite elements whose maximum principal stress exceeds the preset threshold, and calculate a proportion of the high-stress finite elements among all the failed finite elements.

The rock bolt density refers to a quantity of rock bolts to be installed per unit excavation face area, used to characterize a surrounding rock support strength.

In some embodiments, the processor may determine the rock bolt density using a preset empirical mapping relationship between the quantity proportion of the high-stress finite elements and the rock bolt density. For example, a higher quantity proportion of the high-stress finite elements corresponds to a larger rock bolt density. As another example, a specific numerical correspondence relationship between the rock bolt density and the quantity proportion of the high-stress finite elements may be set through a preset empirical mapping curve. For example, a piecewise linear function may be used to map the quantity proportion of the high-stress finite elements to a corresponding rock bolt density.

The excavation face cross-sectional area refers to a tunnel cross-sectional area corresponding to a current construction section. The excavation face cross-sectional area may be obtained according to tunnel design drawings.

In some embodiments, the processor may multiply the determined rock bolt density by the excavation face cross-sectional area to calculate a total quantity of rock bolts to be installed within a current excavation face range, and determine the total quantity as the installation quantity. For example, if the calculated rock bolt density is 1.5 bolts per square meter and the current excavation face cross-sectional area is 10 square meters, the installation quantity is 15 bolts. As another example, during the calculation process, the calculation result may be rounded or rounded up according to actual engineering requirements to ensure reasonableness of the installation quantity.

In some embodiments, the processor may transmit the determined installation quantity of the rock bolts to a control system of the rock bolt jumbo. For example, after receiving the installation quantity, the rock bolt jumbo performs drilling, installation, and tensioning of the rock bolts in the second region according to a preset arrangement pattern autonomously or under remote control of an operator, thereby completing support of the surrounding rock.

In some embodiments of the present disclosure, in the excavated region (the second region), when the finite element satisfies the shear failure condition, a pressure release drilling depth is determined based on a distribution of the failed finite elements. The rock bolt density is determined based on the proportion of the high-stress finite elements, and the installation quantity is calculated accordingly. This achieves dynamic perception of the stress state of the surrounding rock and adaptive adjustment of support measure, effectively reduces an instability risk caused by shear failure, and improves safety of tunnel boring operations, precision of support, and engineering efficiency.

In some embodiments, in response to a failure state of at least one finite element in the second region satisfying the tensile failure condition, the processor may: determine a target grouting parameter of a grouting robot based on second motion information of particles of the REV model inside the at least one failed finite element in the second region and a rock mass type, the target grouting parameter including a target grouting volume, a target grouting rate, and a target grouting pressure; and control the grouting robot to perform a grouting operation in the second region based on the target grouting parameter, including: controlling the grouting robot to perform pumping grouting based on the target grouting volume and the target grouting rate, and adjusting a pump outlet pressure based on the target grouting pressure.

The tensile failure condition refers to a condition to judge whether a stress state of a finite element satisfies the tensile failure. For example, the tensile failure condition may include f^{t}≥0 and h≥0.

In some embodiments, the processor may monitor a stress state of each finite element in the second region in real time, and determine whether the failure state of the finite element reaches the tensile failure condition according to a calculation result of operation 150.

The target grouting parameter refers to a target parameter set used to control the grouting robot to perform the grouting operation. The target grouting volume refers to a total volume of grouting material to be pumped to fill voids in a failure region, and the target grouting volume is measured in liters. The target grouting rate refers to a pumping speed of the grouting material, and the target grouting rate is measured in L/min. The target grouting pressure refers to an outlet pressure during pumping of the grouting material, and the target grouting pressure is measured in MPa. The target grouting pressure is used to ensure that the grouting may effectively fill cracks without causing crack expansion or backflow.

The rock mass type refers to a classification type of the underground rock mass in geological engineering. For example, the rock mass type includes a soft rock, a hard brittle rock, a fault zone, a silty rock mass, or the like. The rock mass type may be obtained from geological survey before construction.

In some embodiments, the processor may determine the target grouting parameter of the grouting robot by querying a preset table. For example, the preset table may be constructed. The preset table may include a correspondence among a maximum particle speed, a maximum particle displacement, the rock mass type, the target grouting volume, the target grouting rate, and the target grouting pressure. The preset table is constructed based on historical grouting reinforcement records that involve the tensile failure, include a plurality of rock mass types, and have good grouting sealing effects.

The processor may collect a plurality of historical grouting reinforcement records. Each of the plurality of historical grouting reinforcement records (hereinafter referred to as the record) may include particle motion information in the record (for example, a maximum displacement and a maximum speed of all REV model particles inside a finite element in the record) and an actually selected grouting parameter in the record. The processor may fill data items in the historical grouting reinforcement records into a preset table for runtime query. The maximum particle displacement characterizes an intensity of structural deformation. The maximum particle speed characterizes an intensity of local disturbance. The maximum particle displacement and the maximum particle speed may be directly obtained from the rock mass model. The historical grouting reinforcement record requires traceable simulation results, that is, motion information of REV model particles inside a finite element in a corresponding region during tensile failure before the grouting corresponding to the record may be obtained. The good grouting sealing effect refers to that after grouting, a structure of a grouting region remains stable continuously within a preset period (for example, no collapse occurs).

The processor may, based on the maximum displacement and the maximum speed of REV model particles inside the failed finite element in the second region and a current rock mass type (for example, the soft rock or the hard brittle rock), search the preset table for a historical record that best matches the current condition, thereby obtaining a corresponding target grouting volume, a corresponding target grouting rate, and a corresponding target grouting pressure.

In some embodiments, the processor may further, based on a machine learning model, input particle motion information and the rock mass type to predict an optimal target grouting parameter.

In some embodiments, the processor may transmit the determined target grouting parameter to a control system of the grouting robot. After receiving the target grouting volume and the target grouting rate, the grouting robot adjusts a pumping system to pump a required total amount of grouting material at a predetermined speed. The grouting robot further adjusts an outlet pressure of a pump in real time according to the target grouting pressure, to ensure that the grouting material may effectively fill cracks while avoiding causing crack expansion or backflow.

In some embodiments of the present disclosure, in response to meeting the tensile failure condition, based on the second motion information of REV particles and the rock mass type, the preset table (or machine learning, etc.) is used to accurately determine the target grouting parameter of the grouting robot. This enables the grouting volume, the grouting rate, and the grouting pressure to accurately match actual failure features, effectively improving responsiveness and sealing effects of surrounding rock grouting support, and ensuring stability and safety of tunnel engineering.

In some embodiments, the processor may: determine an accumulated displacement value based on displacement information in the second motion information of the particles of the REV model inside the at least one failed finite element in the second region; determine a void volume of cracks based on the accumulated displacement value; determine the target grouting volume of the grouting robot based on the void volume of the cracks; determine an average separation speed based on speed information in the second motion information of the particles of the REV model inside the at least one failed finite element in the second region; and determine the target grouting rate and the target grouting pressure of the grouting robot based on the average separation speed.

The accumulated displacement value refers to a total displacement amount of REV model particles inside the failed finite element.

In some embodiments, the processor may: obtain displacement vectors of all REV model particles inside the finite element undergoing the tensile failure through the finite element software, and calculate a displacement magnitude of each particle at a current moment; and accumulate displacement magnitudes of all the particles to form a total displacement, i.e., the accumulated displacement value. For example, during a simulation process, the finite element software records a displacement vector of each particle relative to an initial position thereof in real time, then calculates a Euclidean distance (the displacement magnitude), and sums the displacement magnitudes. As another example, the rock mass model may be directly used to obtain and count the displacement magnitudes of the particles relative to initial positions thereof, and then accumulate the displacement magnitudes. The accumulated displacement value is determined by statistically analyzing the displacement magnitudes of the REV model particles relative to initial positions thereof, which can objectively reflect crack opening and void formation.

The void volume of the cracks is used to determine a size of space to be filled by slurry.

In some embodiments, the processor may treat the accumulated displacement value of all REV model particles inside each finite element undergoing the tensile failure as an equivalent crack width of the finite element; obtain a distribution of finite elements undergoing the tensile failure in the model (which may be directly obtained by the rock mass model); calculate a product of a volume of each finite element undergoing the tensile failure and a corresponding equivalent crack width as a crack volume of the finite element; and sum the crack volumes of all finite elements undergoing the tensile failure, to obtain a result as the void volume of the cracks.

In some embodiments, the processor may determine a basic grouting volume based on the void volume of the cracks using an empirical formula; then adjust the basic grouting volume according to a rock mass material strength (for example, if the rock mass material strength is low, the slurry easily penetrates into pores, and the grouting volume may be appropriately increased) to obtain a required grouting volume, that is, the target grouting volume. For example, if the void volume of the cracks is large, the basic grouting volume is also set correspondingly high. The rock mass material strength may be obtained from a geological survey report and used as a factor for determining an adjustment coefficient, which is applied to adjustment of the basic grouting volume.

The average separation speed refers to an average of speed magnitudes of all REV model particles inside the failed finite element at a current time step.

In some embodiments, the processor may: obtain velocity vectors of all particles inside the finite element undergoing the tensile failure; calculate magnitudes of the velocity vectors of all the particles to obtain speed magnitudes; and average the speed magnitudes to obtain the average separation speed. For example, during the simulation process, the finite element software records a velocity vector of each particle in real time, then calculates a speed magnitude of the velocity vector, and arithmetically averages the speed magnitudes to obtain the average separation speed. The average separation speed is determined based on speed magnitudes of REV model particles relative to initial positions thereof, which can stably characterize an overall dynamic activity level of the failure region, avoiding misjudgment caused by differences in particle motion directions or local synchronous motion.

In some embodiments, the processor may determine the target grouting rate and the target grouting pressure using a preset empirical mapping relationship among the average separation speed, the grouting rate, and the grouting pressure. For example, if the average separation speed is high, it indicates rapid crack propagation, and the grouting rate and the grouting pressure need to be increased to quickly seal the crack and prevent uncontrolled expansion. If the average separation speed is low, it indicates slow crack propagation, and low-speed and low-pressure grouting may be adopted, with a focus on reducing secondary disturbance. As another example, a specific numerical correspondence between the average separation speed and the grouting rate and the grouting pressure may be set through a preset empirical mapping curve, for example, using a piecewise linear function to map the average separation speed to a corresponding grouting rate and a corresponding grouting pressure. In some embodiments, an artificial intelligence algorithm based on fuzzy logic, a neural network, or the like, may also be used to determine the target grouting rate and the target grouting pressure.

In some embodiments of the present disclosure, the accumulated displacement value is determined based on particle displacement information, and then the void volume of the cracks is calculated, based on which the target grouting volume is determined. At the same time, the average separation speed is determined based on particle speed information, based on which the target grouting rate and the target grouting pressure are determined. This achieves dynamic response of grouting parameters to a crack evolution process, significantly improves precision and timeliness of grouting support, and effectively enhances a stability of surrounding rock.

In some embodiments, the processor may: in response to a proportion of the at least one failed finite element in the second region among all finite elements in the second region being higher than a preset hazard threshold, control an acousto-optic alarm to issue an alarm, and predict an ejection trajectory and an accumulation range of fractured rock mass particles based on the second motion information of the particles of the REV model inside the at least one failed finite element in the second region; and determine a hazardous zone based on the ejection trajectory and the accumulation range, and control a laser projector at a tunnel crown to project the hazardous zone onto the second region.

The preset hazard threshold refers to a threshold standard used to determine whether a severe rock mass failure risk occurs. For example, the preset hazard threshold may be that a quantity proportion of finite elements undergoing the tensile failure or the shear failure in the second region is higher than 90%.

The ejection trajectory refers to a motion path of the fractured rock mass particles under an action of internal stress and gravity.

The accumulation range refers to a region formed by final landing points of rock mass particles within a tunnel space after motion of the rock mass particles stops.

In some embodiments, the processor may count a quantity of failed finite elements in the second region in real time and calculate a quantity proportion of the failed finite elements in all finite elements in the second region. When the quantity proportion of the failed finite elements is higher than the preset hazard threshold (e.g., higher than 90%), the processor may control the acousto-optic alarm to issue an alarm to alert on-site construction personnel of a severe rock mass failure risk.

In some embodiments, the processor may obtain a current position and a speed vector of each particle of the REV model inside each of the failed finite elements, performs simplified kinetic prediction (e.g., projectile motion) for the particle, and obtains an ejection trajectory curve based on Newton's laws of motion. The processor further calculates a landing position for each particle and obtains the accumulation range after performing envelope processing. In hazard prediction, calculating the speed of the particles is prioritized, and subsequent contact between the particles may be ignored to improve computational efficiency.

The hazardous zone refers to a spatial projection range constructed from ejection trajectories and landing positions of different particles.

In some embodiments, the processor may construct a spatial projection range based on ejection trajectories and accumulation ranges of different particles as the hazardous zone. For example, all predicted ejection trajectories and accumulation ranges may be geometrically superimposed and merged to form a three-dimensional spatial volume covering a potential risk zone. In some embodiments, a safety margin may also be combined to expand a predicted range of the hazardous zone.

In some embodiments, the processor may transmit geometric data of the determined hazardous zone to the laser projector at the tunnel crown. The laser projector projects a boundary or a range of the hazardous zone in a visual manner (e.g., red laser lines, region filling) in an actual space of the second region based on the received data, thereby intuitively warning on-site personnel of a dangerous position. In some embodiments, other visualization devices (e.g., an LED display, an augmented reality helmet) may be used to present the hazardous zone in addition to the laser projector.

In some embodiments of the present disclosure, rapid and accurate identification of the hazardous zone is achieved by monitoring a rock mass failure degree in real time and predicting ejection trajectories and accumulation ranges of fractured rock mass particles based on particle motion information. Furthermore, by visually projecting the hazardous zone onto a construction site via laser projection, timeliness of hazard warning and efficiency of personnel evacuation are significantly improved, ensuring safety and controllability of tunnel construction.

It should be noted that the foregoing descriptions of processe 100 are intended to be exemplary and illustrative only and do not limit the scope of application of the present disclosure. For those skilled in the art, various corrections and changes may be made to processe 100 under the guidance of the present disclosure. However, these corrections and changes remain within the scope of the present disclosure.

One or more embodiments of the present disclosure provide a system of representative elementary volume (REV) cross-scale simulation for adaptive control in tunnel operations. The system includes at least one memory for storing computer instructions and at least one processor configured to communicate with the at least one memory. When executing the computer instructions, the at least one processor is configured to execute the method of representative elementary volume (REV) cross-scale simulation for adaptive control in tunnel operations according to any embodiment of the present disclosure.

One or more embodiments of the present disclosure provide a non-transitory computer-readable storage medium. The storage medium stores computer instructions. When a computer reads the computer instructions from the storage medium, the computer executes the method of representative elementary volume (REV) cross-scale simulation for adaptive control in tunnel operations according to any embodiment of the present disclosure.

Having thus described the basic concepts, it may be rather apparent to those skilled in the art after reading this detailed disclosure that the foregoing detailed disclosure is intended to be presented by way of example only and is not limiting. Various alterations, improvements, and modifications may occur and are intended to those skilled in the art, though not expressly stated herein. These alterations, improvements, and modifications are intended to be suggested by this disclosure and are within the spirit and scope of the exemplary embodiments of this disclosure.

Moreover, certain terminology has been used to describe embodiments of the present disclosure. For example, the terms “one embodiment,” “an embodiment,” and “some embodiments” mean that a particular feature, structure, or feature described in connection with the embodiment is included in at least one embodiment of the present disclosure. Therefore, it is emphasized and should be appreciated that two or more references to “an embodiment” or “one embodiment” or “an alternative embodiment” in various portions of the present disclosure are not necessarily all referring to the same embodiment. Furthermore, the particular features, structures, or features may be combined as suitable in one or more embodiments of the present disclosure.

Furthermore, the recited order of processing elements or sequences, or the use of numbers, letters, or other designations therefore, is not intended to limit the claimed processes and methods to any order except as may be specified in the claims. Although the above disclosure discusses through various examples what is currently considered to be a variety of useful embodiments of the disclosure, it is to be understood that such detail is solely for description purpose and that the appended claims are not limited to the disclosed embodiments, but, on the contrary, are intended to cover modifications and equivalent arrangements that are within the spirit and scope of the disclosed embodiments. For example, although the implementation of various parts described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. This method of disclosure, however, is not to be interpreted as reflecting an intention that the claimed subject matter requires more features than are expressly recited in each claim. Rather, claimed subject matter may lie in less than all features of a single foregoing disclosed embodiment.

In some embodiments, numbers describing the number of ingredients and attributes are used. It should be understood that such numbers used for the description of the embodiments use the modifier “about”, “approximately”, or “substantially” in some examples. Unless otherwise stated, “about”, “approximately”, or “substantially” indicates that the number is allowed to vary by ±20%. Correspondingly, in some embodiments, the numerical parameters used in the description and claims are approximate values, and the approximate values may be changed according to the required features of individual embodiments. In some embodiments, the numerical parameters should consider the prescribed effective digits and adopt the method of general digit retention. Although the numerical ranges and parameters used to confirm the breadth of the range in some embodiments of the present disclosure are approximate values, in specific embodiments, settings of such numerical values are as accurate as possible within a feasible range.

For each patent, patent application, patent application publication, or other materials cited in the present disclosure, such as articles, books, specifications, publications, documents, or the like, the entire contents of which are hereby incorporated into the present disclosure as a reference. The application history documents that are inconsistent or conflict with the content of the present disclosure are excluded, and the documents that restrict the broadest scope of the claims of the present disclosure (currently or later attached to the present disclosure) are also excluded. It should be noted that if there is any inconsistency or conflict between the description, definition, and/or use of terms in the auxiliary materials of the present disclosure and the content of the present disclosure, the description, definition, and/or use of terms in the present disclosure is subject to the present disclosure.

Finally, it should be understood that the embodiments described in the present disclosure are only used to illustrate the principles of the embodiments of the present disclosure. Other variations may also fall within the scope of the present disclosure. Therefore, as an example and not a limitation, alternative configurations of the embodiments of the present disclosure may be regarded as consistent with the teaching of the present disclosure. Accordingly, the embodiments of the present disclosure are not limited to the embodiments introduced and described in the present disclosure explicitly.

What is claimed is:

1. A method of representative elementary volume (REV) cross-scale simulation for adaptive control in tunnel operations, comprising:
establishing a rock mass engineering scale calculation model, and assigning particle parameters to the rock mass engineering scale calculation model;
dividing the rock mass engineering scale calculation model into a plurality of finite elements, and performing mesh division on the plurality of finite elements, wherein a volume of each of the plurality of finite elements is equal to a representative elementary volume (REV);
presetting a plurality of test blasting parameters, wherein each test blasting parameter includes an explosive type, a charge amount, a blasting hole position, and a detonation sequence;
determining a dynamic load based on at least one of the plurality of test blasting parameters, wherein the dynamic load includes a pressure-time curve;
applying a boundary condition to the rock mass engineering scale calculation model, wherein the boundary condition includes the dynamic load;
determining force information and first motion information of element nodes of the plurality of finite elements, and determining a failure state of each of the plurality of finite elements using a continuous medium method;
determining second motion information of particles of an REV model inside at least one failed finite element using a discontinuous medium method;
determining a propagation path of a blast stress wave in a rock mass based on the first motion information of the element nodes of the plurality of finite elements;
determining a surrounding rock damage degree corresponding to each test blasting parameter based on the propagation path and the failure state of each of the plurality of finite elements;
determining a fragmentation efficiency corresponding to each test blasting parameter based on the second motion information of the particles of the REV model inside the at least one failed finite element;
determining an optimal blasting parameter from the plurality of test blasting parameters based on the surrounding rock damage degree and the fragmentation efficiency; and
controlling a blasting robot to perform a blasting operation based on the optimal blasting parameter, including:
controlling the blasting robot to load an explosive into an optimal blasting hole position based on an optimal explosive type and an optimal charge amount; and
detonating the explosive based on an optimal detonation sequence to complete a blasting task for the rock mass.

2. The method according to claim 1, wherein determining the REV includes:
sampling the rock mass engineering scale calculation model according to a preset length-width-height ratio to establish a plurality of discrete element models having different sizes and an identical shape;
performing a numerical test on each of the plurality of discrete element models, respectively, to obtain a variation log of a rock mass mechanical property index of each of the plurality of discrete element models;
obtaining a target mechanical property index for determining the REV; and
determining a volume of a discrete element model, at which a difference between a rate of change of the target mechanical property index in the variation log of the rock mass mechanical property index and 0 is not greater than a stability threshold, as the REV.

3. The method according to claim 2, wherein the target mechanical property index includes a volumetric joint density and a volumetric joint number.

4. The method according to claim 1, wherein the continuous medium method employs a finite element method.

5. The method according to claim 1, wherein the discontinuous medium method employs a discrete element method.

6. The method according to claim 1, wherein the failure state of each of the plurality of finite elements is determined by judging whether each finite element undergoes a shear failure or a tensile failure.

7. The method according to claim 6, wherein a Mohr-Coulomb criterion and a maximum tensile stress criterion are used to judge whether each finite element undergoes the shear failure or the tensile failure.

8. The method according to claim 7, wherein the judging whether each finite element undergoes the shear failure or the tensile failure includes: for each finite element,
calculating a compressive stress f^{s}, a tensile stress f^{t}, and a shear stress h on the finite element;
in response to f^{s}≤0 and h≤0, determining that the finite element undergoes the brittle shear failure; and
in response to f^{t}≥0 and h≥0, determining that the finite element undergoes the brittle tensile failure.

9. The method according to claim 1, wherein the determining second motion information of particles of an REV model inside at least one failed finite element using a discontinuous medium method includes:
calculating a speed and a displacement of a to-be-calculated particle inside the at least one failed finite element using an interpolation method based on speeds and displacements of the element nodes of the plurality of finite elements.

10. The method according to claim 9, wherein the calculating a speed and a displacement of a to-be-calculated particle inside the at least one failed finite element using an interpolation method based on speeds and displacements of the element nodes of the plurality of finite elements includes:
selecting 2-3 element nodes, which are closest to the to-be-calculated particle, from the element nodes of the plurality of finite elements, and performing an interpolation calculation to obtain the displacement and the speed of the to-be-calculated particle.

11. The method according to claim 1, further comprising:
determining an average stress of element nodes of a plurality of finite elements in a first region based on the force information of the element nodes of the plurality of finite elements;
determining a target thrust cylinder pressure and a target cutterhead rotation speed based on the average stress of the element nodes of the plurality of finite elements in the first region; and
controlling a tunnel boring machine to advance toward the first region based on the target thrust cylinder pressure, and to cut a rock mass in the first region based on the target cutterhead rotation speed.

12. The method according to claim 11, further comprising: obtaining a second region, and in response to a failure state of at least one finite element in the second region satisfying a shear failure condition,
determining a drilling depth based on a distribution of at least one failed finite element in the second region;
controlling a drilling machine to perform drilling based on the drilling depth to release pressure;
determining a quantity proportion of high-stress finite elements based on force information of element nodes of the at least one failed finite element in the second region;
determining a rock bolt density based on the quantity proportion of the high-stress finite elements;
determining an installation quantity based on the rock bolt density and an excavation face cross-sectional area; and
controlling a rock bolt jumbo to install the installation quantity of rock bolts for support.

13. The method according to claim 11, further comprising: obtaining a second region, and in response to a failure state of at least one finite element in the second region satisfying a tensile failure condition,
determining a target grouting parameter of a grouting robot based on second motion information of particles of an REV model inside at least one failed finite element in the second region and a rock mass type, wherein the target grouting parameter includes a target grouting volume, a target grouting rate, and a target grouting pressure; and
controlling the grouting robot to perform a grouting operation in the second region based on the target grouting parameter, including:
controlling the grouting robot to perform pumping grouting based on the target grouting volume and the target grouting rate, and adjusting a pump outlet pressure based on the target grouting pressure.

14. The method according to claim 13, wherein determining the target grouting parameter of the grouting robot includes:
determining an accumulated displacement value based on displacement information in the second motion information of the particles of the REV model inside the at least one failed finite element in the second region;
determining a void volume of cracks based on the accumulated displacement value;
determining the target grouting volume of the grouting robot based on the void volume of the cracks;
determining an average separation speed based on speed information in the second motion information of the particles of the REV model inside the at least one failed finite element in the second region; and
determining the target grouting rate and the target grouting pressure of the grouting robot based on the average separation speed.

15. The method according to claim 13, further comprising:
in response to a proportion of the at least one failed finite element in the second region among all finite elements in the second region being higher than a preset hazard threshold, controlling an acousto-optic alarm to issue an alarm, and predicting an ejection trajectory and an accumulation range of fractured rock mass particles based on the second motion information of the particles of the REV model inside the at least one failed finite element in the second region; and
determining a hazardous zone based on the ejection trajectory and the accumulation range, and controlling a laser projector at a tunnel crown to project the hazardous zone onto the second region.

16. The method according to claim 1, further comprising:
determining a maximum speed of the particles of the REV model inside the at least one failed finite element based on the second motion information of the particles of the REV model inside the at least one failed finite element;
in response to the maximum speed being lower than a preset speed threshold, marking the at least one failed finite element as an equivalent finite element; and
in response to an acceleration of an element node of a finite element corresponding to the equivalent finite element exceeding a preset acceleration threshold, marking the equivalent finite element as a failed finite element.

17. A system of representative elementary volume (REV) cross-scale simulation for adaptive control in tunnel operations, comprising:
at least one memory for storing computer instructions; and
at least one processor configured to communicate with the at least one memory, wherein when the at least one processor executes the computer instructions, the at least one processor is configured to:
establish a rock mass engineering scale calculation model, and assigning particle parameters to the rock mass engineering scale calculation model;
divide the rock mass engineering scale calculation model into a plurality of finite elements, and performing mesh division on the plurality of finite elements, wherein a volume of each of the plurality of finite elements is equal to a representative elementary volume (REV);
preset a plurality of test blasting parameters, wherein each test blasting parameter includes an explosive type, a charge amount, a blasting hole position, and a detonation sequence;
determine a dynamic load based on at least one of the plurality of test blasting parameters, wherein the dynamic load includes a pressure-time curve;
apply a boundary condition to the rock mass engineering scale calculation model, wherein the boundary condition includes the dynamic load;
determine force information and first motion information of element nodes of the plurality of finite elements, and determining a failure state of each of the plurality of finite elements using a continuous medium method;
determine second motion information of particles of an REV model inside at least one failed finite element using a discontinuous medium method;
determine a propagation path of a blast stress wave in a rock mass based on the first motion information of the element nodes of the plurality of finite elements;
determine a surrounding rock damage degree corresponding to each test blasting parameter based on the propagation path and the failure state of each of the plurality of finite elements;
determine a fragmentation efficiency corresponding to each test blasting parameter based on the second motion information of the particles of the REV model inside the at least one failed finite element;
determine an optimal blasting parameter from the plurality of test blasting parameters based on the surrounding rock damage degree and the fragmentation efficiency; and
control a blasting robot to perform a blasting operation based on the optimal blasting parameter, including:
controlling the blasting robot to load an explosive into an optimal blasting hole position based on an optimal explosive type and an optimal charge amount; and
detonating the explosive based on an optimal detonation sequence to complete a blasting task for the rock mass.

18. A non-transitory computer-readable storage medium, wherein the storage medium stores computer instructions, and when a computer reads the computer instructions from the storage medium, the computer executes a method of representative elementary volume (REV) cross-scale simulation for adaptive control in tunnel operations including:
establishing a rock mass engineering scale calculation model, and assigning particle parameters to the rock mass engineering scale calculation model;
dividing the rock mass engineering scale calculation model into a plurality of finite elements, and performing mesh division on the plurality of finite elements, wherein a volume of each of the plurality of finite elements is equal to a representative elementary volume (REV);
presetting a plurality of test blasting parameters, wherein each test blasting parameter includes an explosive type, a charge amount, a blasting hole position, and a detonation sequence;
determining a dynamic load based on at least one of the plurality of test blasting parameters, wherein the dynamic load includes a pressure-time curve;
applying a boundary condition to the rock mass engineering scale calculation model, wherein the boundary condition includes the dynamic load;
determining force information and first motion information of element nodes of the plurality of finite elements, and determining a failure state of each of the plurality of finite elements using a continuous medium method;
determining second motion information of particles of an REV model inside at least one failed finite element using a discontinuous medium method;
determining a propagation path of a blast stress wave in a rock mass based on the first motion information of the element nodes of the plurality of finite elements;
determining a surrounding rock damage degree corresponding to each test blasting parameter based on the propagation path and the failure state of each of the plurality of finite elements;
determining a fragmentation efficiency corresponding to each test blasting parameter based on the second motion information of the particles of the REV model inside the at least one failed finite element;
determining an optimal blasting parameter from the plurality of test blasting parameters based on the surrounding rock damage degree and the fragmentation efficiency; and
controlling a blasting robot to perform a blasting operation based on the optimal blasting parameter, including:
controlling the blasting robot to load an explosive into an optimal blasting hole position based on an optimal explosive type and an optimal charge amount; and
detonating the explosive based on an optimal detonation sequence to complete a blasting task for the rock mass.
